(19) United States
(12) Patent Application Publication
(10) Pub. No.: US 2013/0283253 A1
(43) Pub. Date: Oct. 24, 2013

(54) WATER-COOLING THERMAL DISSIPATING SYSTEM, THERMAL DISSIPATIING METHOD THEREOF, AND FIRMWARE UPDATING METHOD THEREOF

(71) Applicant: ENERMAX TECHNOLOGY CORPORATION, Taoyuan County (TW)

(72) Inventors: Jer-Sheng HWANG, Taoyuan County (TW); Teng-Kai CHANG, Taoyuan County (TW); Chin-Chen CHU, Taoyuan County (TW)

(73) Assignee: ENERMAX TECHNOLOGY CORPORATION, Taoyuan County (TW)

(21) Appl. No.: 13/845,729

(22) Filed: Mar. 18, 2013

(30) Foreign Application Priority Data
Apr. 23, 2012 (TW) 101114395

(51) Int. Cl. H05K 7/20

(52) U.S. Cl. CPC H05K 7/20136; H05K 7/20281
USPC 717/168; 361/699; 361/695

(57) ABSTRACT

A water-cooling thermal dissipation system is connected to an electronic device for dissipating heat generated by a thermal generating member. The electronic device includes a motherboard where the heat generating member disposed. The water-cooling heat dissipation system includes at least one thermal-cycling loop, a controlling module, and a connecting member. A cooling liquid of the thermal-cycling loop flows in at least one pump and at least one thermal exchanger through a plurality pipes. The controlling module is electrically connected to the thermal-cycling loop and monitors the operating temperatures of the thermal generating member and the cooling liquid, and outputs a warning signal when one of operation temperatures of the thermal generating member and the cooling liquid is higher than a predetermined value. The connecting member is connected to the controlling module and the motherboard, so that signals can transmit between the controlling module and the motherboard.

### BACKGROUND OF THE INVENTION

1. Field of the Invention

The present invention relates to a thermal dissipating system, and in particular to a water-cooling thermal dissipating system, a thermal dissipating method of the water-cooling thermal dissipating system, and a firmware updating method of the water-cooling thermal dissipating method.

2. Description of Related Art

Computer application and people's life are inseparable because the improvement of word-processing ability of computer and software, and more and more students and office workers completely prearranged work and entertainment by computer.

The integrated circuits (ICs) disposed within the computer become smaller and small, however, the heat generated by the operating ICs become higher and higher, especially the heat generated by the central processing unit (CPU) is the highest so as to increase the temperatures around the CPU. The high temperature environment operation will slower the operating speed of the ICs, and is a main reason for damaging the ICs.

In order to solve the problem mentioned above, a part of manufacturers use heat tanks, fans and water-cooling thermal dissipating system to collectively conducted heat. However, conventional water-cooling thermal dissipating system cannot communicate with software installed in the computer or warn user when unusual operation or damage. Such that the water-cooling thermal dissipating system is damaged or even blasting because user cannot instantaneously close a part of operated programs or enhance thermal dissipating ability of the water-cooling thermal dissipating system, and then the computer is consequentially damaged.

### SUMMARY OF THE INVENTION

It is an object to provide a water-cooling thermal dissipating system. The water-cooling thermal dissipating system is electrically connected to an electronic device via a connecting member, such that signals can transmit between the electronic device and the water-cooling thermal dissipating system via the connecting member.

It is another object to provide a thermal dissipating method of the water-cooling thermal dissipating system. The thermal dissipating method implements self-condition inspection after the electronic device is booted and an electric power is corrected, and a cooling monitoring procedure is then implemented to increase safety of the water-cooling thermal dissipating system.

It is still another object to provide a firmware updating method of the water-cooling thermal dissipating system.

Accordingly, the water-cooling thermal dissipating system according to one aspect of the present invention is connected to an electronic device for dissipating heat generated by a thermal generating member disposed within the electronic device. The electronic device comprises a motherboard, a power supply unit electrically connected to the motherboard, and a displaying unit. The thermal dissipating member is disposed on the motherboard. The water-cooling thermal dissipating system comprises at least one thermal-cycling loop, a controlling module, and a connecting member.

The thermal-cycling loop comprises a cooling liquid, at least one pump, and at least one thermal exchanger. The pump communicates with the thermal generating member via a plurality of pipes, the cooling liquid flows within the pump, the thermal generating member, and the pipes. The controlling module is electrically connected to the thermal-cycling loop and monitoring operating temperatures of the thermal generating member and the cooling liquid, wherein the controlling module outputs a warning signal to the motherboard when one of the operating temperatures of the thermal generating member and the cooling liquid is higher than a predetermined temperature, the motherboard makes the warning signal show on the displaying unit.

The connecting member is contacted with the controlling module and the motherboard, such that the warning signal is transmitted between the controlling module and the motherboard.

Accordingly, the thermal dissipating method according to another aspect of the present invention is implemented after an electronic device is booted and a power supply unit finishes a booting procedure. The electronic device comprises a motherboard and a displaying unit, the power supply unit and the display unit are electrically are connected to the motherboard. The water-cooling thermal dissipating system is connected to the motherboard via a connecting member and then achieving electric power and signals transmission.

The water-cooling thermal dissipating system comprises at least one thermal-cycling loop. The thermal-cycling loop comprises at least one pump, at least one fan, a plurality of pipes, at least one thermal exchanger, and a cooling liquid flowing within the thermal generating member, the pipes, the pumps, and the thermal exchanger. The fan and the thermal exchanger collectively conduct heat generating by the thermal generating member.

The thermal dissipating method comprises: a) implementing self-condition inspecting procedure; b) sensing whether an operating temperature of the cooling liquid is higher than a first predetermined temperature, and sensing whether an operating temperature of the thermal generating member is higher than a second predetermined temperature; c) outputting a first warning signal when the operating temperature of the cooling liquid being higher than the first predetermined temperature, and outputting a second warning signal when the temperature of the thermal generating member being higher than the second predetermined temperature; and d) showing at least one of the first warning signal and the second warning signal on the displaying unit controlled by the motherboard.

Accordingly, the firmware updating method according to still another aspect of the present invention is used for updating a firmware of a water-cooling thermal dissipating system, the water-cooling thermal dissipating system comprising a microprocessor, a memory, and a connecting member. The memory is electrically connected to the microprocessor, and a target firmware is stored within the memory, the microprocessor is electrically connected to a server via the connecting member. The firmware updating method comprises: a) catching at least one updating firmware when receiving a firmware updating command; b) locking the target firmware; and c) replacing the target firmware with updating firmware.

The connecting member of the water-cooling thermal dissipating system according to the present invention is USB, such that a function of plug and play is provided, and is convenient to use. Moreover, the self-condition inspecting procedure of the thermal dissipating method is prior implemented after the electronic device implementing the booting procedure and electric power correcting procedure, such that the damage of the electronic device causes by unusual water-cooling thermal dissipating system is prevented. Furthermore, the cooling monitoring procedure is implemented after the booting procedure of the electronic device is finished, warning the user when the operating temperature of the thermal generating member and the cooling liquid is over temperature, and forcing to shut down the electronic device when the rotating speeds of the fan and the pump are respectively higher than the first rotating speed and the second rotating speed, such that the safety of usage is enhanced.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1 is a schematic view of a water-cooling thermal dissipating system according to a first embodiment of the present invention.

FIG. 2A is a circuit diagram of the water-cooling thermal dissipating system according to the first embodiment of the present invention.

FIG. 2B is a circuit diagram of a water-cooling thermal dissipating system according to a second embodiment of the present invention.

FIG. 3A is a flowchart showing steps for booting an electronic device according to the present invention.

FIG. 3B is a flowchart showing steps for a thermal dissipating method of the water-cooling thermal dissipating system according to the present invention.

FIG. 4 is a flowchart showing steps for a self-condition inspection according to the present invention.

FIG. 5 is a circuit diagram of a water-cooling thermal dissipating system according to a third embodiment of the present invention.

### DETAILED DESCRIPTION OF THE INVENTION

A preferred embodiment of the present invention will be described with reference to the drawings.

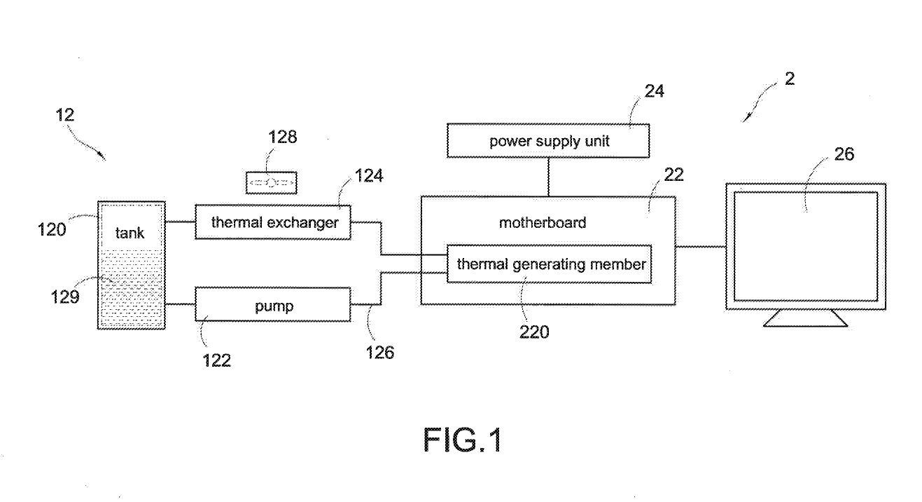

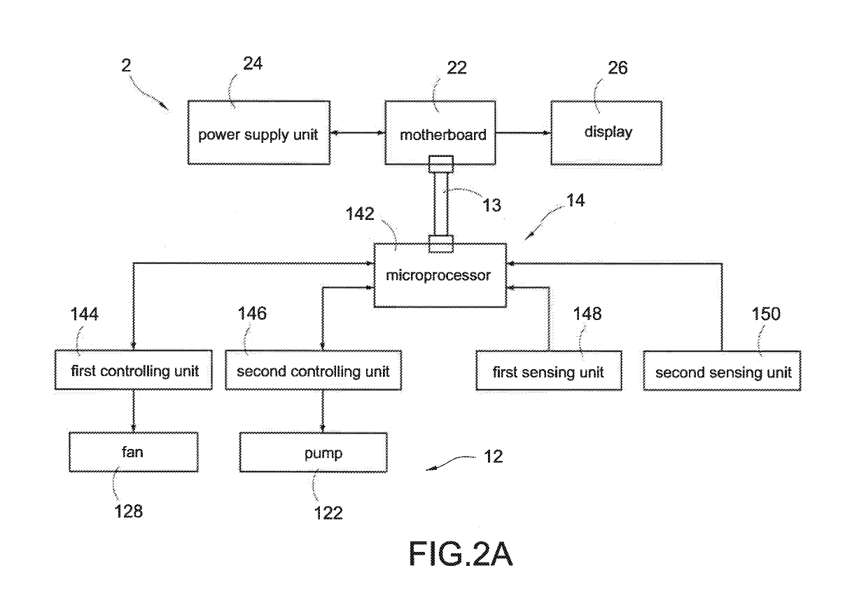

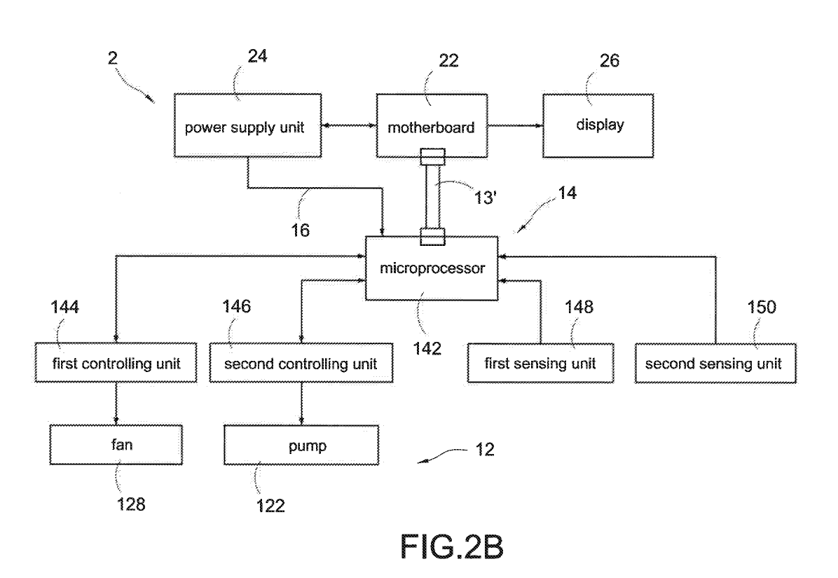

Reference is made to FIG. 1 and FIG. 2A, which are respectively a schematic view and a circuit diagram of a water-cooling thermal dissipating system according to a first embodiment of the present invention. The water-cooling thermal dissipating system is used for conducting heat generated by an operating electronic device 2 to prevent the electronic device 2 from operating under high temperature which increases unstable operating of members and units installed in the electronic device 2 or even damages the electronic device 2. The electronic device 2 is, for example, computer or server.

The electronic device 2 includes a motherboard 22, a power supply unit 24, a displaying unit 26, and at least one thermal generating member 220 disposed on the motherboard 22. The amount of the thermal generating member 220 can be one or more, and the thermal generating member 220 is preferably central processing unit (CPU). However, in the practical application, the thermal generating member 220 can be any member or unit disposed on the motherboard 22, such as graphic processing unit (GPU). The power supply unit 24 is electrically connected to the motherboard 22 and provides electric power to the electronic device 2.

The displaying unit 26 is configured to show pictures when the electronic device 2 is operated. The display unit 26 and the motherboard 22 can be packaged within one case, or the display unit 26 is installed apart from the motherboard 22 and electrically connected to the motherboard 22 via a signal line (not shown). The displaying unit 26 is, for example, a liquid crystal display (LCD).

The water-cooling thermal dissipating system is installed into a slot (not shown) of the electronic device 2. However, the water-cooling thermal dissipating system can be installed apart from the electronic device 2. The water-cooling thermal dissipating system includes at least one thermal-cycling loop 12, a connecting member 13, and a controlling module 14. The amount of the thermal-cycling loop 12 can be one or more, and the amount of the thermal-cycling loop is preferably equal to the amount of the thermal generating member 220 to effectively and rapidly conducted heat generated by the thermal generating member 220. In this embodiment, the amount of the thermal-cycling loop 12 is, for example, one. If the water-cooling thermal dissipating system includes more than one thermal-cycling loops 12, the thermal-cycling loops 12 are electrically connected to the controlling module 13, respectively, such that the controlling module 14 can simultaneously control operating states of the thermal-cycling loops 12.

The thermal-cycling loop 12 includes at least one pump 122 and at least one thermal exchanger 124. The amount of the pump 122 and the thermal exchanger 124 can respectively be one or more, and in this embodiment, the thermal cycling loop 12 includes one pump 122 and one thermal exchanger 124. The pump 122 communicates with the thermal exchanger 124 via a plurality of pipes 126, such that a cooling liquid 129 (such as water) can flow within the pump 122, the thermal exchanger 124, and the pipes 126. The thermal-cycling loop 12 can further include a tank 120 communicating with the pump 122 and the thermal exchanger 124 via the pipes 126, such that the cooling liquid 129 can flow within the tank 120, the pump 122, the thermal exchanger 124, and the pipes 126.

The pipes 126 is connected to the thermal generating member 220 disposed within the electronic device 2, such that thermal exchange effect is implemented between the cooling liquid 129 and the thermal generating member 220, and heat generated by the thermal generating member 220 is then conducted. The cooling liquid 129 is stored in the tank 120, and is forced to flow within the pipes 126 by the pump 122. The thermal exchanger 124 is configured to compulsively dissipate heat. The thermal exchanger 124 can be condenser or thermal dissipating fins. The thermal exchanger 124 and at least one fan 128 collectively dissipate heat generating by the thermal generating member 220. The amount of the fan 128 can be one or more, and in this embodiment, the amount of the fan 128 is, for example, one.

With referred again to FIG. 2A. The connecting member 13 is connected to the motherboard 22 and the controlling module 14, such that the electric power generated by the power supply unit 24 is conducted to the controlling module 14 via the motherboard 22 and the connecting member 13. Moreover, signals outputted by the controlling module 14 are transmitted to the motherboard 22 via the connected member 13, and signals outputted by the motherboard 22 are transmitted to the controlling module 14 via the connecting member 13. In this embodiment, the connecting member 13 is, for example, universal series bus (USB). However, in the practical application, the signals can be wireless transmitted between the motherboard 22 and the controlling module 14.

The controlling module 14 includes a microprocessor 142, at least one controlling unit, and at least one sensing unit. In this embodiment, the controlling unit of the controlling module 14 includes a first controlling unit 144 and a second controlling unit 146, and the sensing unit of the controlling module 14 includes a first sensing unit 148 and a second sensing unit 150.

The task of the microprocessor 142 is to coordinate and direct all the data transmission and operation between the members and units, and connected to the motherboard 22 via the connecting member 13. The first controlling unit 144 is electrically connected to the microprocessor 142 and the fan 128. The first controlling unit 144 is configured to sense and control a rotating speed of the fan 128, and outputs a fist abnormal signal to the microprocessor 142 when the rotating speed of the fan 128 is abnormal. The microprocessor 142 transmits the first abnormal signal to the motherboard 22 via the connecting member 13, and the motherboard 22 makes the first abnormal signal show on the displaying unit 26. Therefore, user can be informed that the fan 128 is abnormal, and then decide whether to continually use the electronic device 2.

The second controlling unit 146 is electrically connected to the microprocessor 142 and the pump 122. The second controlling unit 146 is configured to control a rotating speed of the pump 122 and a flowing rate of the cooling liquid 129 flowing through the pump 122, and outputs a second abnormal signal to the microprocessor 142 when the rotating speed of the pump 122 or the flowing rate of the cooling liquid 129 flowing through the pump 122 is abnormal. The microprocessor 142 transmits the second abnormal signal to the motherboard 22 via the connecting member 13, and the motherboard 22 makes the second abnormal signal show on the displaying unit 26. Such that user can be informed that the pump 122 of the water-cooling thermal dissipating system is abnormal, and then decides whether to continually use the electronic device 2.

The first sensing unit 148 is electrically connected to the microprocessor 142. The first sensing unit 148 is configured to sense an operating temperature of the cooling liquid 129, and outputs a first warning signal to the microprocessor 142 when the operating temperature of the cooling liquid 129 is higher than a first predetermined temperature (such as 50 degree Celsius). The microprocessor 142 transmits the first warning signal to the motherboard 22 via the connecting member 13, and then the motherboard 22 makes the first warning signal show on the displaying unit 26. Such that user can be informed that the cooling liquid 129 of the water-cooling thermal dissipating system is over temperature, and then user can shut down the electronic device 2 or enhance thermal dissipating effect of the water-cooling thermal dissipating system by manually or automatically increase the rotating speed of the fan 128 or pump 122. The first sensing unit 148 further senses a level of the cooling liquid 129 to prevent the water-cooling thermal dissipating system from breakdown causing by low level.

The second sensing unit 150 is electrically connected to the microprocessor 142. The second sensing unit 150 is configured to sense an operating temperature of the thermal generating member 220, and output a second warning signal when the operating temperature of the thermal generating member 220 is higher than a second predetermined temperature (such as 70 degree Celsius). Such that user can be informed that the thermal generating member 220 is over temperature, and then user can shut down the electronic device 2 or enhance thermal dissipating effect of the water-cooling thermal dissipating system by manually or automatically increase the rotating speed of the fan 128 or pump 122

Reference is made to FIG. 2B, which is a circuit diagram of a water-cooling thermal dissipating system according to a second embodiment of the present invention. The water-cooling thermal dissipating system shown in FIG. 2B is similar to the water-cooling thermal dissipating system shown in FIG. 2A, and the same reference numbers are used in the drawings and the description to refer to the same parts. The difference is that the water-cooling thermal dissipating system shown in FIG. 2B further includes a power line 16.

The power line 16 is electrically connected to the power supply unit 24 and the controlling module 14 for transmitting electric power generated by the power supply unit 24 to the controlling module 14. The connecting member 13′ is simultaneously connected to the motherboard 22 and the controlling module 14 for transmitting signals between the motherboard 22 and the controlling module 14, such that a better electronic isolating is provided. In this embodiment, the connecting member 13′ is, for example, universal series bus (USB). The function and relative description of other components of the water-cooling thermal dissipating system are the same as that of first embodiment mentioned above and are not repeated here, and the water-cooling thermal dissipating system in this embodiment can fulfill the functions as the water-cooling thermal dissipating system in the first embodiment does.

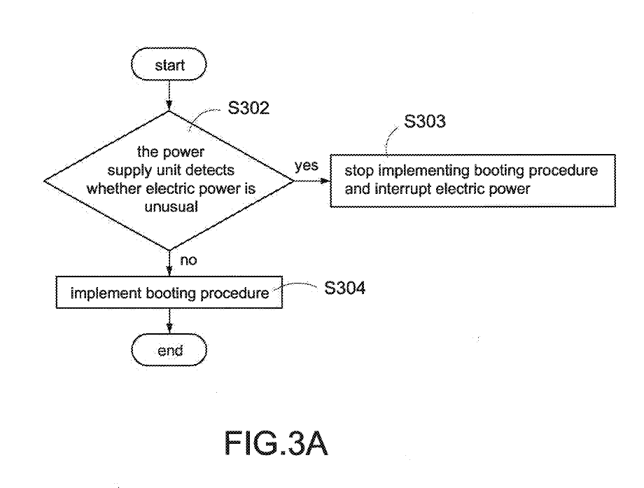

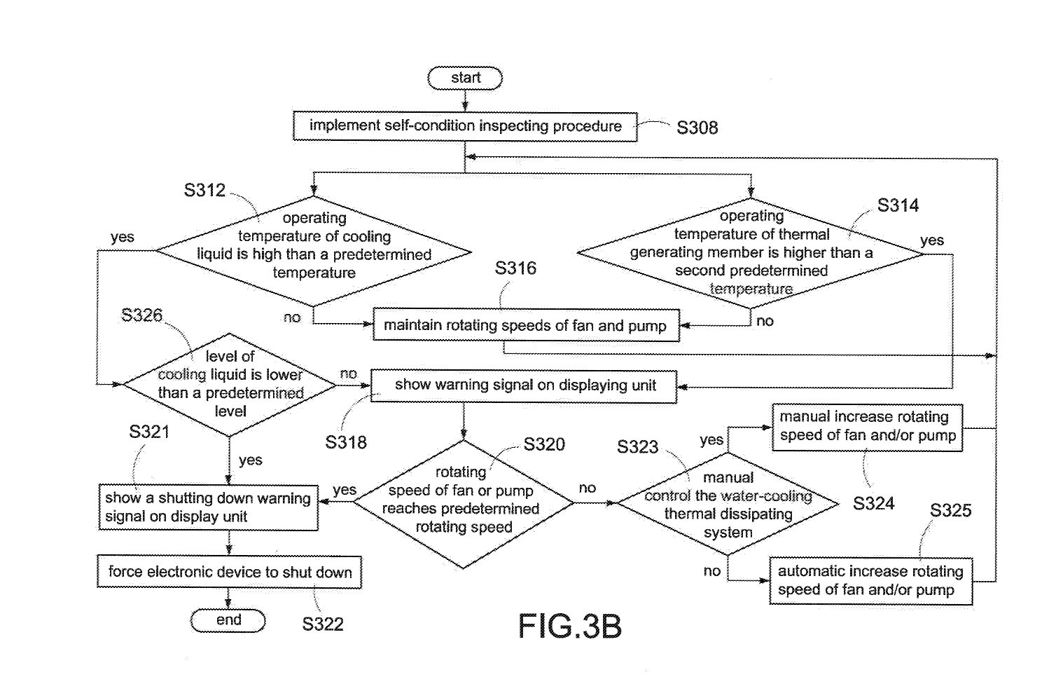

Reference is made to FIG. 3A, which is a flowchart showing steps for booting an electronic device according to the present invention. At first, the power supply unit 24 of the electronic device 2 implements procedure of electric power correction when a user presses a button for booting an electronic device 2 having the water-cooling thermal dissipating system. In step S302, a correction is made as to whether the power supply unit 24 is unusual. When the power supply unit 24 is usual, the electric power is outputted and transmitted to thee motherboard 22 to implement booting procedure of the electronic device 2 (step S304), and when the power supply unit 24 is unusual, the booting procedure is stopped implementing and the electric power is interrupted (step S303). In particularly, the booting procedure of the electronic device 2 is the same as that of in currently and is not repeated here.

Reference is made to FIG. 3B, which is a flowchart showing steps for thermal dissipating method of the water-cooling thermal dissipating system according to the present invention. When the booting procedure of the electronic device 2 (step S304) is completely implemented, a self-condition inspecting procedure is then implemented (step S308). The purpose of the self-condition inspecting procedure is made to whether the thermal-cycling loop 12 is unusual, namely, to whether the pump 122, the fan 128 and the cooling liquid 129 is unusual to prevent the water-cooling thermal dissipating system from breakdown.

After implementing the self-condition inspection (step S308), a cooling monitoring procedure is then implemented. The cooling monitoring procedure includes: at first, the controlling module 14 senses whether the operating temperature of the cooling liquid 129 is high than a predetermined temperature via the first sensing unit 128 (step S312), and the controlling module senses whether the operating temperature of the thermal generating member 220 is higher than a second predetermined temperature via the second sensing unit 150 (step S314).

After step S312, when the temperature of the cooling liquid 129 is lower than the first predetermined temperature, the rotating speeds of the fan 128 and the pump 122 are maintained (step S316), and then back to step S312 to implement cooling monitoring procedure.

After step S312, when the temperature of the cooling liquid 129 is higher than the first predetermined temperature, the first sensing unit 148 sensing whether the level of the cooling liquid 129 is lower than a predetermined level (step S326). When the level of the cooling liquid 129 is lower than a predetermined level, a level low signal is outputted by the first sensing unit 148 and transmitted to motherboard 22 via the microprocessor 142 and the connecting member 13. The motherboard 2 makes the displaying unit 26 show a shutting down warning signal (step S321) and force the electronic device 2 to shut down in a predetermined time (such 30 seconds) after showing the shutting down warning signal on the displaying unit 26 (step S322).

When the cooling liquid 129 is higher than the predetermined level, a first warning signal is outputted by the first sensing unit 48. The first warning signal at least includes an over temperature massage of the cooling liquid 129 and a current temperature of the cooling liquid 129. The first warning signal is transmitted to the motherboard 22 via the microprocessor 142 and connecting member 13, and then shown on the displaying unit 26 controlled by the motherboard 22 (step S318).

In step S302, the first controlling unit 144 senses whether the rotating speed of the fan 128 is reaching a first predetermined rotating speed (such as 2400 RPM), and the second controlling unit 146 senses whether the rotating speed of the pump 122 is reaching a second predetermined rotating speed (such as 4500 rpm). When the rotating speed of the fan 128 reaches the first predetermined rotating speed, a forcefully shutting down signal is outputted by the first controlling unit 144 and transmitted to the motherboard 22 via the microprocessor 142 and the connecting member 13. The motherboard 22 makes the displaying unit 26 show the shutting down warning signal, and force the electronic device 2 to shut down in a predetermined time (such 30 seconds) after showing the shutting down warning signal on the displaying unit 26 (step S322).

When the rotating speed of the pump 122 reaches the second predetermined rotating speed, a forcefully shutting down signal is outputted by the second controlling unit 146 and transmitted to the motherboard 22 via the microprocessor 142 and the connecting member 13. The motherboard 22 makes the displaying unit 26 show the shutting down warning signal, and force the electronic device 2 to shut down in a predetermined time after showing the shutting down warning signal on the displaying unit 26 (step S322).

After step S320, when the rotating speed of the fan 128 does not reach the first predetermined rotating speed, and the rotating speed of the pump 122 does not reach the second rotating speed, user can select whether to manual control the water-cooling thermal dissipating system (step S323).

When user selects to manual control to water-cooling thermal dissipating system, controlling commands can be inputted by the electronic device 2 to increase rotating speeds of the fan 128 and/or the pump 122 (step S324), such that the thermal dissipating ability of the water-cooling thermal dissipating system can be enhanced. After that, back to the step S312 and step S314 to implement cooling monitoring procedure.

After step S323, when user does not select to manual control the water-cooling thermal dissipating system, the microprocessor 142 automatic regulates the rotating speeds of the fan 128 or/and the pump 122 according to the operating temperatures of the cooling liquid 129 and the thermal generating member 220 (step S325) to enhance thermal dissipating ability of the water-cooling thermal dissipating system. After that, back to step S312 and step S314 to implement cooling monitoring procedure.

After step S314, when the operating temperature of the thermal generating member 220 is lower than the second predetermined temperature, the rotating speed of the fan 128 and the pump 122 is maintained. After that, back to step S314 to implement cooling monitoring procedure. However, when the operating temperature of the thermal generating member 220 is higher than the second predetermined temperature, a second warning signal is outputted by the second sensing unit 150. The second warning signal includes an over temperature massage of the thermal generating member 220 and a current temperature of the thermal generating member 220. The second warning signal is transmitted to the motherboard 22 via the microprocessor 142 and connecting member 13, and then shown on the displaying unit 26 controlled by the motherboard 22 (step S318).

After that, the first controlling unit 128 senses whether the rotating speed of the fan 128 is reaching the first predetermined rotating speed, and the second controlling unit 146 senses whether the rotating speed of the pump 122 is reaching the second predetermined rotating speed (step S320).

When the rotating speed of the fan 128 reaches the first predetermined rotating speed, a forcefully shutting down signal is outputted by the first controlling unit 144 and transmitted to the motherboard 22 via the microprocessor 142 and the connecting member 13. The motherboard 22 makes the displaying unit 26 show the shutting down warning signal, and force the electronic device 2 to shut down in a predetermined time after showing the shutting down warning signal on the displaying unit 26 (step S322). Moreover, when the rotating speed of the pump 122 reaches the second predetermined rotating speed, a forcefully shutting down signal is outputted by the second controlling unit 146 and transmitted to the motherboard 22 via the microprocessor 142 and the connecting member 13. The motherboard 22 makes the displaying unit 26 show the shutting down warning signal, and force the electronic device 2 to shut down in a predetermined time after showing the shutting down warning signal on the displaying unit 26 (step S322).

After step S320, when the rotating speed of the fan 128 does not reach the first predetermined rotating speed, and the rotating speed of the pump 122 does not reach the second rotating speed, user can select whether to manual control the water-cooling thermal dissipating system (step S323).

When user selects to manual control to water-cooling thermal dissipating system, controlling commands can be inputted by the electronic device 2 to increase rotating speeds of the fan 128 and/or the pump 122 (step S324), such that the thermal dissipating ability of the water-cooling thermal dissipating system can be enhanced. After that, back to step S312 and step S314 to implement cooling monitoring procedure.

When user does not select to manual control the water-cooling thermal dissipating system, the microprocessor 142 automatic regulates the rotating speeds of the fan 128 or/and the pump 122 according to the operating temperatures of the cooling liquid 129 and the thermal generating member 220 (step S325) to enhance thermal dissipating ability of the water-cooling thermal dissipating system. After that, back to step S312 and step S314 to implement cooling monitoring procedure.

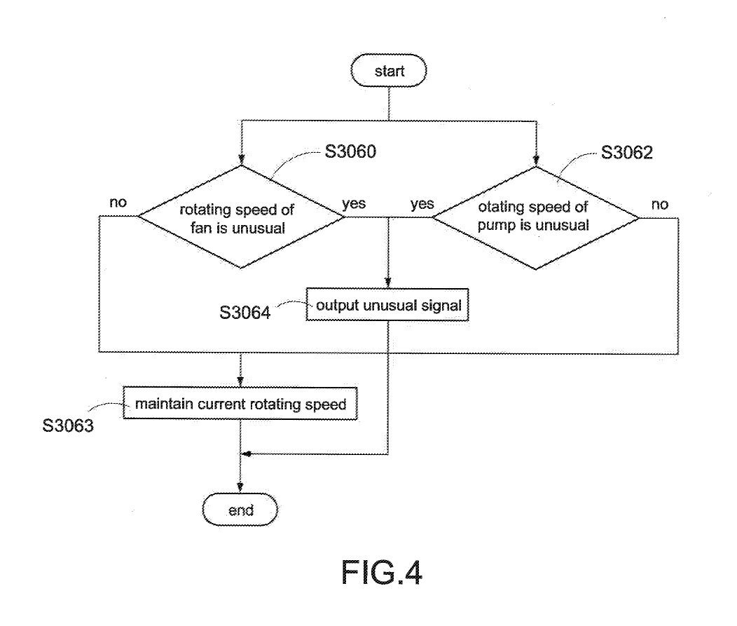

Reference is made to FIG. 4, which is a flowchart showing steps for a self-condition inspection according to the present invention. The self-condition inspection of step S308 includes steps shown in FIG. 4. At first, the first controlling unit 144 senses whether a rotating speed of the fan 128 is unusual (step S3060), and the second controlling unit 146 senses whether a rotating speed of the pump 122 is unusual (step S3062).

When the rotating speed of the fan 128 sensed by the first controlling unit 144 is unusual, a first unusual signal is outputted and transmitted to the microprocessor 142 (step S3064). The first unusual signal includes an unusual massage of the fan 128 and current rotating speed of the fan 128. The first unusual signal is transmitted to the motherboard 22 via the connecting member 13 by the microprocessor 142, and is shown by the displaying unit 26 controlled by the motherboard 22. When the rotating speed of the fan 128 sensed by the first controlling unit 144 is usual, the rotating speed of the fan 128 is maintained (step S3063).

After step S3062, when the rotating speed of the pump 122 sensed by the second controlling unit 146 is unusual, a second unusual signal is outputted and transmitted to the microprocessor 142 (step S3064). The first unusual signal includes an unusual massage of the pump 122 and current rotating speed of the pump 122. The second unusual signal is transmitted to the motherboard 22 via the connecting member 13 by the microprocessor 142, and is shown by the displaying unit 26 controlled by the motherboard 22. When the rotating speed of the pump 122 sensed by the second controlling unit 146 is usual, and the rotating speed of the pump 122 is maintained (step S3063).

To sum up, the connecting member 13 is the water-cooling thermal dissipating member is USB, such that a function of plug and play is provided, and is convenient to use. Moreover, the self-condition inspecting procedure of the thermal dissipating method is prior implement after the electronic device 2 implementing the booting procedure and electric power correcting procedure, such that the damage of the electronic device 2 causes by unusual water-cooling thermal dissipating system is prevented. Furthermore, the cooling monitoring procedure is implemented after the booting procedure of the electronic device 2 is finished, warning the user when the operating temperature of the thermal generating member 220 and the cooling liquid 129 is over temperature, and forcing to shut down the electronic device 2 when the rotating speeds of the fan 128 and the pump 122 are respectively higher than the first rotating speed and the second rotating speed, such that the safety of usage is enhanced.

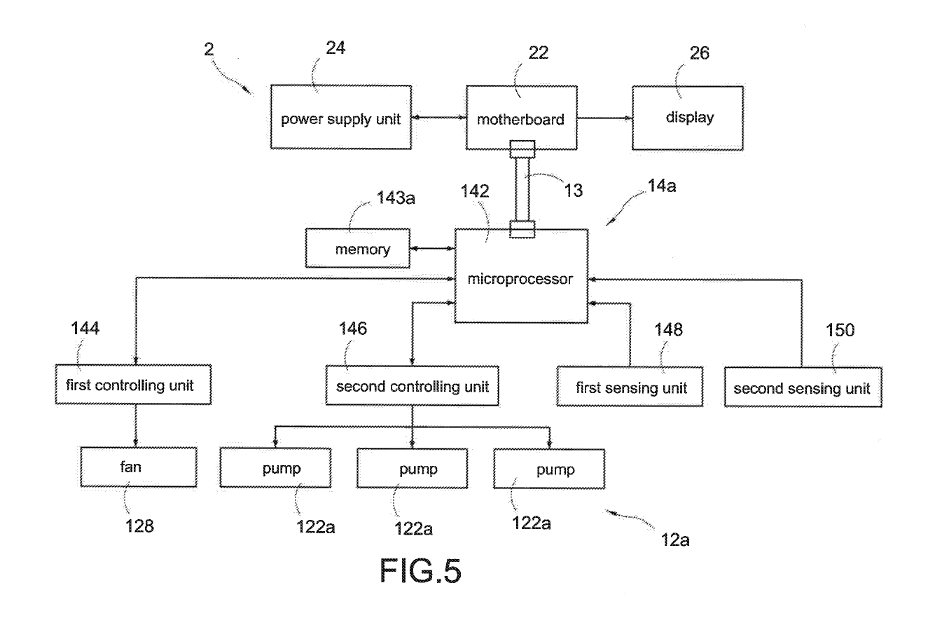

Reference is made to FIG. 5, which is a circuit diagram of a water-cooling thermal dissipating system according to a third embodiment of the present invention. The water-cooling thermal dissipating system shown in FIG. 5 is similar to the water-cooling thermal dissipating system shown in FIG. 1, and the same reference numbers are used in the drawings and the description to refer to the same parts. The difference is that the water-cooling thermal dissipating system shown in FIG. 5 includes a plurality of pump 122a, and a controlling module 14a includes a memory 143a.

The pumps 122a are electrically connected to the second controlling unit 146 in parallel. In this embodiment, the thermal-cycling loop 12a includes three pumps 122a. In the practical application, the water-cooling thermal dissipating system can start only one pump 122a, and then the cooling liquid 129 (as shown in FIG. 1) will flow within the tank 120, the pump 122a and the thermal exchanger 124. When an unusual operating of the pump 122a is sensed by the second controlling unit 146, another pump 122a is automatic started and the broken pump 122a is stopped operating to achieve pump 122a replacement to maintain usual operating of the water-cooling thermal dissipating system.

The memory 143a is electrically connected to the microprocessor 132 and a plurality of firmware for controlling the thermal-cycling loop are stored therein. The microprocessor 142 reads the firmware from the memory 143a and implements the firmware to control the thermal-cycling loop 12. The memory 143a is non-volatile memory, such as programmable read only memory (PROM), erasable programmable ROM (EPROM), electrically erasable programmable ROM (EEPROM) or flash memory.

The electronic device 2 is connected to a server (not shown) via network connection to download at least one updating firmware. After that, the firmware stored within the memory 143a is updated by the connecting member 13 connected between the microprocessor 142 and the motherboard 22. An update method of the water-cooling thermal dissipating system includes:

Catching at least one updating firmware by network transmission when a firmware updating command is received by the electronic device 2. In the practical application, the method for catching the updating firmware is not limited by network transmission, and can be replaced by reading disc, USB or other data transmission method.

After that, at least one target firmware stored within the memory 143a is locked, and then the target firmware is replaced by the updating firmware to complete firmware updating operation of the water-cooling thermal dissipating system.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A water-cooling thermal dissipating system connected to an electronic device for dissipating heat generated by a thermal generating member disposed within the electronic device, the electronic device comprising a motherboard, a power supply unit electrically connected to the motherboard, and a displaying unit, the thermal dissipating member disposed on the motherboard, the water-cooling thermal dissipating system comprising:
at least one thermal-cycling loop comprising a cooling liquid, at least one pump, and at least one thermal exchanger, the pump communicating with the thermal generating member via a plurality of pipes, the cooling liquid flowing within the pump, the thermal generating member, and the pipes;
a controlling module electrically connected to the thermal-cycling loop and monitoring operating temperatures of the thermal generating member and the cooling liquid, wherein the controlling module outputs a warning signal to the motherboard when one of the operating temperatures of the thermal generating member and the cooling liquid is higher than a predetermined temperature, the motherboard makes the warning signal show on the displaying unit; and
a connecting member contacted with the controlling module and the motherboard, such that the warning signal is transmitted between the controlling module and the motherboard.

2. The water-cooling thermal dissipating system in claim 1, wherein an electric power generated by the power supply unit is transmitted to the controlling module via the connecting member.

3. The water-cooling thermal dissipating system in claim 1, further comprising a power line electrically connected to the power supply unit and the controlling module.

4. The water-cooling thermal dissipating system in claim 1, wherein the controlling module comprises at least one microprocessor, at least one controlling unit and at least one sensing unit, the microprocessor is electrically connected to the connecting member, the controlling unit and the sensing unit are electrically connected to the microprocessor.

5. The water-cooling thermal dissipating system in claim 4, wherein the thermal-cycling loop further comprises at least one fan electrically connected to the controlling module, the fan and the thermal exchanger collectively dissipate heat generating by the thermal generating member.

6. The water-cooling thermal dissipating system in claim 5, wherein the controlling module further comprises:
a first controlling unit electrically connected to the microprocessor and the fan, the first controlling unit configured to control and sense rotating speed of the fan;
a second controlling unit electrically connected to the microprocessor and the pump, the second controlling unit configured to control and sense rotating speed of the pump;
a first sensing unit electrically connected to the microprocessor and configured to sense a temperature and a level of the cooling liquid; and
a second sensing unit electrically connected to the microprocessor and configured to sense an operating temperature of the thermal generating member.

7. The water-cooling thermal dissipating system in claim 5, wherein the controlling unit monitors the operating state of the water-cooling thermal dissipating system, and outputs at least one unusual signal to the motherboard via the connecting member when at least one of the fan and pump is unusual, the motherboard makes the unusual signal show on the displaying unit.

8. The water-cooling thermal dissipating system in claim 1, wherein the connecting member is a universal series bus (USB).

9. The water-cooling thermal dissipating system in claim 1, wherein the thermal-cycling loop further comprises a tank communicating with the pump and the thermal exchanger via the pipes, the cooling liquid flows in the tank, the pump, the thermal exchanger, and the pipes.

10. The water-cooling thermal dissipating system in claim 1, wherein an amount of the thermal-cycling loop is equal to an amount of the thermal generating member.

11. The water-cooling thermal dissipating system in claim 4, wherein the controlling module further comprises a memory electrically connected to the microprocessor, the memory is configured store firmware for controlling the thermal-cycling loop.

12. The water-cooling thermal dissipating system in claim 6, wherein the thermal-cycling loop further comprises a plurality of pumps electrically connected to the second controlling unit in parallel.

13. A thermal dissipating method dissipating heat generating by a thermal generating member disposed within an electronic device and implemented after an electronic device being started and a power supply unit finishing a booting procedure, the electronic device comprising a motherboard and a displaying unit, the power supply unit and the display unit electrically connected to the motherboard, the water-cooling thermal dissipating system connected to the motherboard via a connecting member and then achieving electric power and signals transmission, the water-cooling thermal dissipating system comprising at least one thermal-cycling loop, the thermal-cycling loop comprising at least one pump, at least one fan, a plurality of pipes, at least one thermal exchanger, and a cooling liquid flowing within the thermal generating member, the pipes, the pumps, and the thermal exchanger, the fan and the thermal exchanger collectively conducting heat generating by the thermal generating member, the thermal dissipating method comprising:
a) implementing self-condition inspecting procedure;
b) sensing whether an operating temperature of the cooling liquid is high than a first predetermined temperature, and sensing whether an operating temperature of the thermal generating member is higher than a second predetermined temperature;
c) outputting a first warning signal when the operating temperature of the cooling liquid being higher than the first predetermined temperature, and outputting a second warning signal when the temperature of the thermal generating member being higher than the second predetermined temperature; and
d) showing at least one of the first warning signal and the second warning signal on the displaying unit controlled by the motherboard.

14. The thermal dissipating method in claim 13, wherein step a further comprises:
a1) sensing whether the rotating speeds of the fan and the pump is unusual;
a2) when the rotating speed of the fan is unusual, the water-cooling thermal dissipating system outputs a first unusual signal, and when a rotating speed of the pump is unusual, the water-cooling thermal dissipating system outputs a second unusual signal;
a3) showing at least one of the first unusual signal and the second unusual signal on the displaying unit controlled by the motherboard.

15. The thermal dissipating method in claim 13, further comprising a following step after the step b:
when the operating temperatures of the cooling liquid is lower than the first predetermined temperature, and the operating temperature of the thermal generating member is lower than the second predetermined temperature, the rotating speeds of the fan and pump are maintained.

16. The thermal dissipating method in claim 13, further comprising following steps after the step d:
e) sensing whether a rotating speed of the fan is reaching a first rotating speed, and sensing whether a rotating speed of the pump reaching a second rotating speed;
f) when the rotating speed of the fan reaches the first rotating speed or the rotating speed of the pump reaches the second rotating speed, the display unit shows a shutting down warning signal and forcing to shut down the electronic device after a predetermined time; and
g) when the rotating speed of the fan does not reach the first rotating speed and the rotating speed of the pump does not reach the second rotating speed, increasing at least one of the rotating speeds of the fan and pump.

17. The thermal dissipating method in claim 13, further comprising a flowing step after the step c:
when a temperature is higher than a first predetermined temperature and a level of the cooling liquid is lower than a predetermined level, a shutting down warning signal is shown on the display unit, and the electronic device is forced to shut down the electronic device after a predetermined time

18. The thermal dissipating method in claim 13, wherein the connecting member is a universal series bus (USB).

19. A firmware updating method is used for updating a firmware of a water-cooling thermal dissipating system, the water-cooling thermal dissipating system comprising a microprocessor, a memory, and a connecting member, the memory electrically connected to the microprocessor, and a target firmware stored within the memory, the microprocessor electrically connected to a server via the connecting member, the firmware updating method comprising:
a) catching at least one updating firmware when receiving a firmware updating command;
b) locking the target firmware; and
c) replacing the target firmware with updating firmware.
